(19) United States
(12) Patent Application Publication
(10) Pub. No.: US 2025/0096154 A1
(43) Pub. Date: Mar. 20, 2025

(54) Package Substrates with Stiffener Interposers

(71) Applicant: Intel Corporation, Santa Clara, CA (US)

(72) Inventors: Chin Mian CHOONG, Georgetown (MY); Jiun Hann SIR, Gelugor (MY); Poh Boon KHOO, Perai (MY); Juha PAAVOLA, Hillsboro, OR (US)

(21) Appl. No.: 18/466,844

(22) Filed: Sep. 14, 2023

(51) Int. Cl. H01L 23/00; H01L 21/48; H01L 23/15; H01L 23/498; H01L 23/552

(52) U.S. Cl. CPC H01L 23/562; H01L 21/4853; H01L 21/4857; H01L 21/486; H01L 23/15; H01L 23/49816; H01L 23/49822; H01L 23/49833; H01L 23/49838; H01L 23/552

(57) ABSTRACT

The present disclosure is directed to a stiffener having a first lateral member and a vertical member that form a frame structure that encloses around a package substrate of a semiconductor package, and the vertical member having an upper end connected to the first lateral member and a lower end extending downward from the first lateral member for connecting to a printed circuit board.

### BACKGROUND

For integrated circuit design and fabrication, the need to improve performance and lower costs are constant challenges. The high-volume manufacturing (HVM) of semiconductor packages may produce yield losses caused by package warpage during the assembly process; in particular, for semiconductor packages using thin cores or coreless package substrates. Package warpage may be the result of multiple factors such as coefficient of thermal expansion (CTE) mismatches, the stack-up of different types of components, and the various thermal processing steps that the semiconductor packages undergo during the assembly process.

A commonly used approach to controlling warpage uses a mechanical part, such as a stiffener, to improve the strength of package substrates and minimize the warpage. The stiffener enhances the durability of the package substrate by adding thickness and reinforcing, for example, the areas in which components will be mounted. However, it is often the case that the stiffener is weakly grounded or not grounded, ie., “floating”, and will have microstrip signal routings underneath or near the stiffener. Such stiffeners may act as antennas to radiate RF emissions and may degrade an electronic platform system's Wi-Fi signal and wireless throughput data rate by adding extra radio frequency interference (RFI), i.e., RFI noise, to the platform system.

To mitigate the RFI, a current approach uses several ground stitching vias around the edges of the package to minimize the coupling and interference. However, to compensate for the ground stitching vias adjacent to power planes and HSIO signals routing area on the surface microstrip of the package substrate, the edges of the package substrates may need to be extended, which increases package real estate and is also undesirable.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 shows an exemplary representation of a conventional semiconductor package with a stiffener;

FIG. 2 shows an exemplary representation of a semiconductor package with a present stiffener according to an aspect of the present disclosure;

FIGS. 3, 3A, and 3B show an exemplary representation of a semiconductor package with another present stiffener according to an aspect of the present disclosure;

FIGS. 4 and 4A show an exemplary representation of a semiconductor package with yet another present stiffener according to an aspect of the present disclosure;

FIGS. 5A and 5B show comparison images for exemplary simulations for vertical deflections of semiconductor packages according to another aspect of the present disclosure;

FIG. 6 shows an exemplary method for forming the present ceramic stiffeners according to an aspect of the present disclosure;

FIGS. 7A through 7F show an exemplary method of assembling a semiconductor package with a present stiffener according to an aspect of the present disclosure; and

FIG. 8 shows a simplified flow diagram for an exemplary method according to an aspect of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

According to the present disclosure, the present stiffener may be positioned around a package substrate to provide a very stiff construction for effective warpage control, as compared to the conventional flat metal stiffener, without jeopardizing an end product's size (i.e., length and width), and thickness (i.e., z-direction height). The present stiffeners may be most suitable for thin core or coreless package substrates; in particular, package substrates having a thickness of less than 1 mm. The present stiffener may have various cross-sectional shapes, including an inverted L-shape, a sideway U-shape, and a zig-zag shape. The present stiffeners may also be stiffener interposers that act as an electrical bridge to provide additional current flow paths for power to the package substrate and may be soldered and coupled to a printed circuit board (PCB).

The present disclosure provides a stiffener having a first lateral member and a vertical member that form a frame structure that encloses around a package substrate of a semiconductor package, and the vertical member having an upper end connected to the first lateral member and a lower end extending downward from the first lateral member for connecting to a printed circuit board.

The present disclosure is also directed to a method including forming a stiffener having a first lateral member and a vertical member, providing a package substrate having a top surface, side surfaces, and a bottom surface for forming a semiconductor package, disposing at least one semiconductor device onto the top surface of the package substrate to form the semiconductor package, and disposing the stiffener on the package substrate, for which the first lateral member is disposed on the top surface and the vertical member is proximal to the side surfaces of the package substrate.

The present disclosure is further directed to an electronic component having a semiconductor package including a coreless package substrate having a periphery, a plurality of solder balls attached to the package substrate, a frame structure enclosing the periphery of the package substrate, and the plurality of solder balls, and a printed circuit board. In an aspect, the frame structure and the plurality of solder balls are electrically coupled to the printed circuit board.

The technical advantages of the present disclosure include, but are not limited to:
(i) providing stiffener structures that can provide improved warpage control for thin core and coreless substrates:
(ii) providing stiffener structures with electrical pathways that act as interposers for additional current flow and grounding with a printed circuit board;
(iii) providing stiffener structures made of ceramic material to avoid RF interference caused by metal stiffeners; and
(iv) providing stiffener structures that maintain the form factor for semiconductor packages used in electronic components and systems.

To more readily understand and put into practical effect the present stiffener interposer structures and the semiconductor packages using them, which may provide improved warpage control and reduced RF interference, particular aspects will now be described by way of examples provided in the drawings that are not intended as limitations. The advantages and features of the aspects herein disclosed will be apparent through reference to the following descriptions relating to the accompanying drawings. Furthermore, it is to be understood that the features of the various aspects described herein are not mutually exclusive and can exist in various combinations and permutations. For the sake of brevity, duplicate descriptions of features and properties may be omitted.

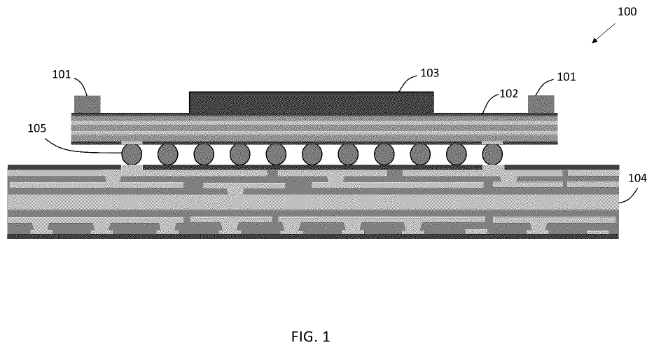

FIG. 1 shows an exemplary representation of a conventional semiconductor package 100 with a stiffener 101. The stiffener 101 is typically a flat metal structure that is positioned near the periphery of an upper surface of a package substrate 102. If the package substrate 102 is a coreless substrate, the warpage control may be difficult. The stiffener 101 is typically made of metal and is not grounded or only weakly grounded, which may cause it to act as an antenna and generate RF interference. A die 103 may be mounted on the package substrate 102. The semiconductor package may have solder balls 105, which may be surface mounted onto a printed circuit board 104. The shortcomings of the typically used flat metal stiffeners are addressed by the present stiffeners described below.

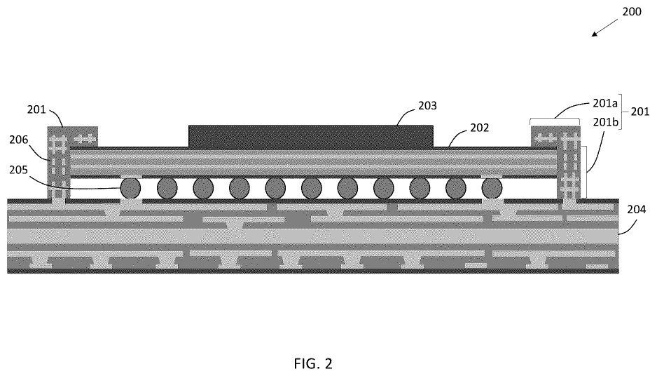

FIG. 2 shows an exemplary representation of a semiconductor package 200 with a present stiffener 201 according to an aspect of the present disclosure. The semiconductor package 200 may have a package substrate 202, a die 203, a printed circuit board 204, and a plurality of solder balls 205 coupling the package substrate 202 with the printed circuit board 204. The stiffener 201 may have a first lateral member 201a and a vertical member 201b, which form a cross-section that is approximately an inverted L-shape. The vertical member 201b can provide additional rigidity and stability for warpage control.

In an aspect, the vertical member 201b may have an upper end joined to the first lateral member 201a and a lower end extending downward from the first lateral member 201a for connecting to the printed circuit board 204. In addition, the vertical member 201b should have a sufficient length to accommodate the solder balls 205. The stiffener 201 may provide greater warpage control and stability by having the first lateral member 201a being disposed on the top surface of the package substrate 202 and having the vertical member 201b engaging or being closely proximal to the side surfaces of the package substrate 202 and its lower end attached to the printed circuit board 204 as shown in FIG. 2. The stiffener 201 may be grounded to printed circuit board 204 to minimize EMI/RFI coupling and interference with any microstrip signal routing underneath the semiconductor package 200.

In another aspect, the stiffener 201 may act as an interposer providing an electrical bridge between the semiconductor package 200 and the printed circuit board 204. The first lateral member 201a and the vertical member 201b may be made of a ceramic material and may be additionally provided with metallization layers (e.g., routing/signal lines, power lines, and ground lines) and vias for electrical pathways 206 between components on the package substrate 202 and components on the printed circuit board 204 (both such components are not shown).

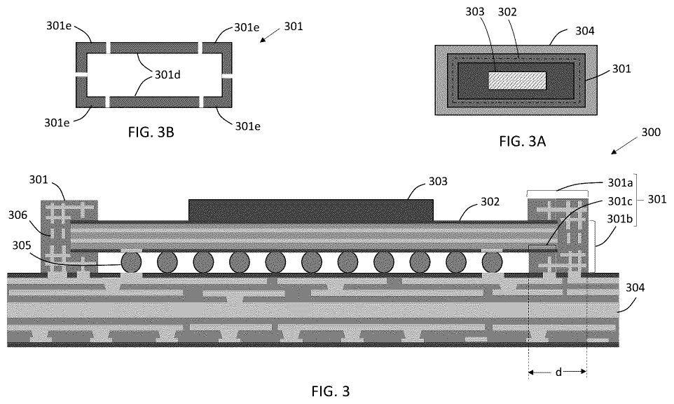

FIGS. 3, 3A, and 3B show an exemplary representation of a semiconductor package 300 with another present stiffener 301 according to another aspect of the present disclosure. In FIG. 3, the semiconductor package 300 may have a package substrate 302, a die 303, a printed circuit board 304, and a plurality of solder balls 305 coupling the package substrate 302 with the printed circuit board 304. In this aspect, the stiffener 301 may have a first lateral member 301a, a vertical member 301b, and a second lateral member 301c, which form a cross-section that is approximately a sideways U-shape. The second lateral member 301c extends horizontally inward towards the solder balls 305 and generally is within a vertical footprint d of the first lateral member 301a. The vertical member 301b and the second lateral member 301c can provide additional rigidity and stability for warpage control.

In an aspect, the vertical member 301b may have an upper end joined to the first lateral member 301a, and a lower end extending downward from the first lateral member 301a for connecting to the printed circuit board 304 and for joining the second lateral member 301c. In addition, the vertical member 301b should have a sufficient length to accommodate the solder balls 305. The stiffener 301 may provide greater warpage control and stability by having the first lateral member 301a being disposed on the top surface of the package substrate 302, having the vertical member 301b engaging or being closely proximal to the side surfaces of the package substrate 302, and having the second lateral member 301c engaging or being closely proximal to the bottom surface of the package substrate 302. In addition, the lower end of the vertical member 301b and the second lateral member 301c may be attached to the printed circuit board 304 as shown in FIG. 3. The stiffener 301 may be grounded to printed circuit board 304 to minimize EMI/RFI coupling and interference with any microstrip signal routing underneath the semiconductor package 300.

In another aspect, the stiffener 301 may act as an interposer providing an electrical bridge between the semiconductor package 300 and the printed circuit board 304. The first lateral member 301a, the vertical member 301b, and the second lateral member 301c may be made of a ceramic material, and may be additionally provided with metallization layers (e.g., routing/signal lines, power lines, and ground lines) and vias for electrical pathways 306 between components on the package substrate 302 and components on the printed circuit board 304 (both such components are not shown).

In yet another aspect, as shown in 3B, the stiffener 301 may be an assembled frame structure made from several subcomponents. For example, the stiffener 301 may include four corner subcomponents 301e and two straight sides 301d that are placed around the package substrate 202 and joined together. It should be understood that there are various configurations for the subcomponents that may be made for assembly to form a present stiffener.

In FIG. 3A, a top view of the semiconductor package 300 is shown. The present stiffener 301 may enclose or otherwise frame the package substrate 302, which has a periphery shown by the dash lines. The stiffener 301 may have a larger footprint than the package substrate 302 to provide improved stability for warpage control.

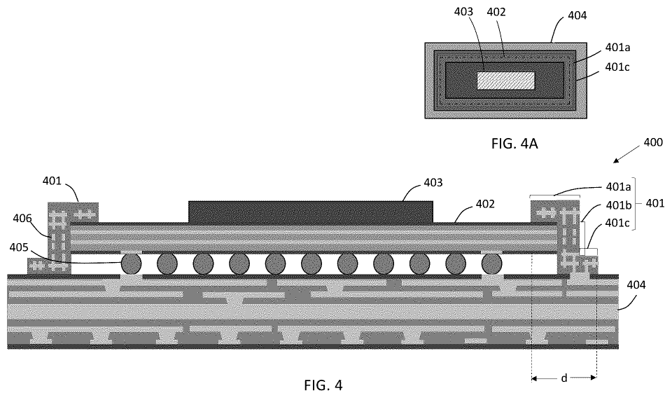

FIGS. 4 and 4A show an exemplary representation of a semiconductor package 400 with yet another present stiffener 401 according to yet another aspect of the present disclosure. In FIG. 4, the semiconductor package 400 may have a package substrate 402, a die 403, a printed circuit board 404, and a plurality of solder balls 405 coupling the package substrate 402 with the printed circuit board 404. In this aspect, the stiffener 401 may have a first lateral member 401a, a vertical member 401b, and a second lateral member 401c which form a cross-section that is approximately a zig-zag shape. The second lateral member 401c extends horizontally outward away from the solder balls 405 and generally extends a vertical footprint d of the stiffener 401. The vertical member 401b and second lateral member 401c can provide additional rigidity and stability for warpage control.

In an aspect, the vertical member 401b may have an upper end joined to the first lateral member 401a and a lower end extending downward from the first lateral member 401a for connecting to the printed circuit board 404 and for joining the second lateral member 401c. In addition, the vertical member 401b should have a sufficient length to accommodate the solder balls 405. The stiffener 401 may provide greater warpage control and stability by having the first lateral member 401a being disposed on the top surface of the package substrate 402, having the vertical member 401b engaging or being closely proximal to the side surfaces of the package substrate 402, and having the lower end of the vertical member 401b and the second lateral member 401c attached to the printed circuit board 404 as shown in FIG. 4. The stiffener 401 may be grounded to printed circuit board 404 to minimize EMI/RFI coupling and interference with any microstrip signal routing underneath the semiconductor package 400.

In another aspect, the stiffener 401 may act as an interposer providing an electrical bridge between the semiconductor package 400 and the printed circuit board 404. The first lateral member 401a, the vertical member 401b and the second lateral member 401c may be made of a ceramic material, and may be additionally provided with metallization layers (e.g., routing/signal lines, power lines, and ground lines) and vias for electrical pathways 406 between components on the package substrate 402 and components on the printed circuit board 404 (both such components are not shown).

In FIG. 4A, a top view of the semiconductor package 400 is shown. The present stiffener 401 may enclose or otherwise frame the package substrate 402, which has a periphery shown by the dash lines. The stiffener 401 may have a larger footprint, as provided by the second lateral member 401c, than the package substrate 402, which may provide further stability for warpage control.

It should be understood that the present stiffeners may have a variety of shapes and sizes and are not limited to the inverted L-shape, the sideways U-shape, and the zig-zag shape described above. The shape and size of a particular stiffener may be designed to accommodate the shape and size of a package substrate, as well as the routing lines on both the package substrate and a printed circuit board that the stiffener will be thereon attached. For example, a present stiffener may have a first lateral member with a thickness that is thinner than a thickness for a die used in a semiconductor package. In another example, a present stiffener may have a vertical footprint in the range of approximately 0.5 to 3.0 mm.

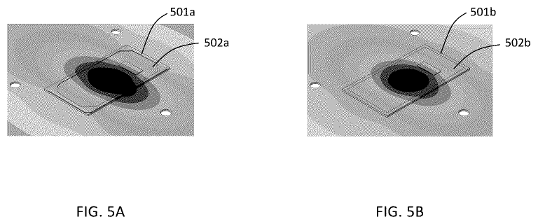

FIGS. 5A and 5B show comparison images for exemplary simulations for vertical deflections of semiconductor packages according to another aspect of the present disclosure. With the use of electrical test board (ETB) simulation modeling, comparison results may be obtained for vertical deflection (mm) and using a die loading of 25N (approximately 11.4 pound force) between a conventional flat frame stiffener and a present stiffener. A present stiffener having a sideway U-shape was used in FIG. 5B and showed an approximately 31% improvement (reduction) for package deflection over the conventional flat frame stiffener that was used in FIG.

5A. Similarly, simulations for a present stiffener having an inverted L-shape provided an approximately 21% improvement and for a present stiffener having a zig-zag shape provided an approximately 23% improvement.

Since the present ceramic stiffener interposer may be made of high modulus material, as discussed below, and the CTE is closer to that of a silicon die, it will better compensate for any “cry” shape warpage at room temperature and any “smile” shape warpage at high temperature compared to a typical metal frame stiffener.

In addition, the present stiffeners may permit the design of semiconductor packages that avoid the need for backplates and corner glue when the warpage is within specified thresholds.

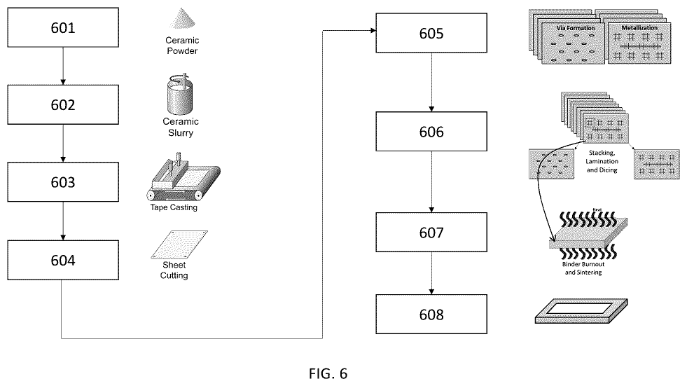

FIG. 6 shows an exemplary method for forming the present ceramic stiffeners according to an aspect of the present disclosure. In step 601, a grounded and sieved ceramic powder may be selected, such as silicon carbide, alumina, silicon nitride, zirconia, various titanates, yttrium oxides, and mixtures thereof, to make the present ceramic stiffeners. In step 602, a ceramic slurry may be obtained by mixing the ceramic powder, a carrying vehicle, a binder, and a dispersant, thereby producing a uniformly dispersed ceramic slurry. In step 603, a fabrication technique called tape casting may be used to produce large thin ceramic sheets from the ceramic slurry. In step 604, the large sheets may be cut to the sizes needed for further processing. In step 605, to form electrical pathways in a present stiffener, a screen printing technique may be used to lay out the pathways, followed by the drilling of vias and metallization using a metal, such as copper. In step 606, the metalized sheets may be shaped and the various sheets stacked/assembled to form laminated structures, which may be diced into smaller pieces with the inverted L-shape, sideways U-shape, or zig-zag shape. In step 607, heat may be applied to burn out the binder and sinter the ceramic laminated structures. In step 608, the present ceramic stiffeners, or the parts needed for assembly into the present ceramic stiffeners, may be produced as the final products.

It should be understood that the present ceramic stiffeners may be made using other methods; for example, using a ceramic casting method and/or 3D printing.

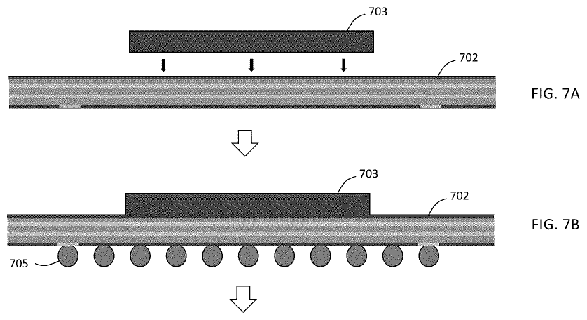

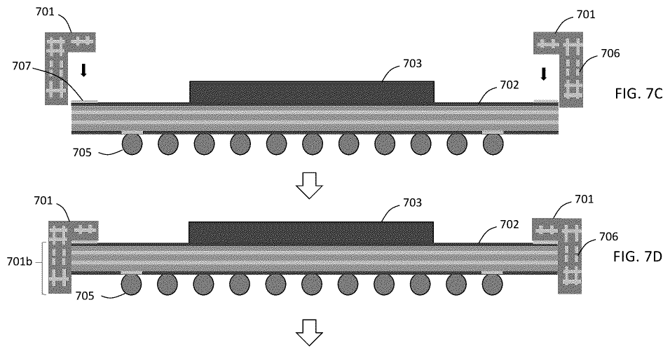

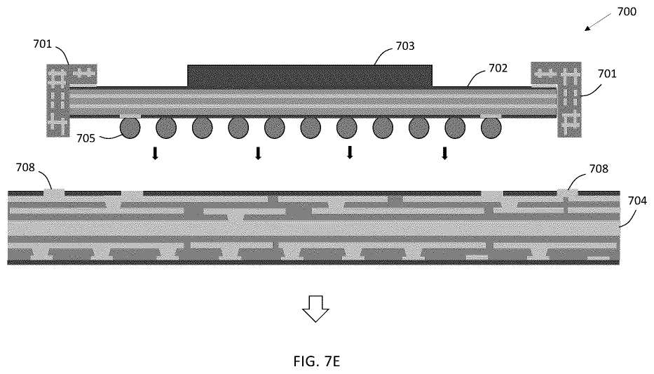

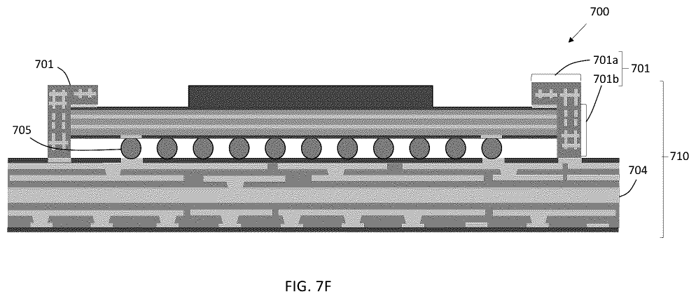

FIGS. 7A through 7F show an exemplary method of making and assembling a semiconductor package with a present stiffener according to an aspect of the present disclosure. In FIG. 7A, a die 703 may be mounted on a package substrate 702 using conventional surface mounting technology. In FIG. 7B, a plurality of solder balls 705, i.e., a ball grid array, may be placed on a bottom surface of the package substrate 702. In FIG. 7C, a pre-formed present stiffener 701 having an inverted L-shape may be positioned over the package substrate 702 to align with an adhesive 707, e.g., a solder paste, placed proximal to the periphery of the package substrate 702. The adhesive 707 may be connected to a ground layer (not shown) in the printed circuit board 704. In FIG. 7D, the stiffener 701 is shown enclosing the periphery of the package substrate and having a vertical member 701b that extends to enclose the plurality of solder balls 705. In FIG. 7E, the semiconductor package 700 may be mounted onto a printed circuit board 704 with the stiffener 701 coupled with a pad 708 and the plurality of solder balls 705 coupled with the printed circuit board 704 by using a surface mounting process. In FIG. 7F, the assembled semiconductor package 700, and printed circuit board 704 may be an electronic component 710 for a mobile phone or other device.

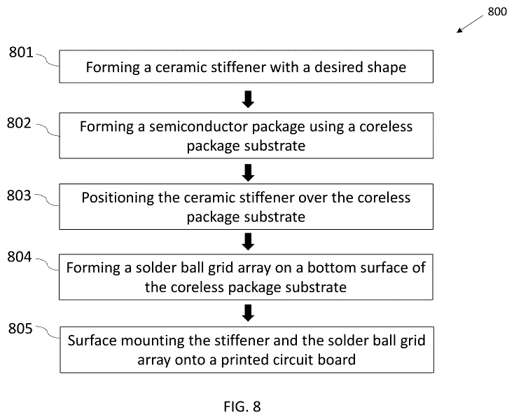

FIG. 8 shows a simplified flow diagram for an exemplary method 800 according to an aspect of the present disclosure.

The operation 801 may be directed to forming a ceramic stiffener with a desired shape.

The operation 802 may be directed to forming a semiconductor package using a coreless package substrate.

The operation 803 may be directed to positioning the ceramic stiffener over the coreless package substrate.

The operation 804 may be directed to forming a solder ball grid array on a bottom surface of the coreless package substrate.

The operation 805 may be directed to surface mounting the stiffener and the solder ball grid array onto a printed circuit board.

It will be understood that any property described herein for a particular stiffener structure and method for forming a semiconductor package may also hold for any electronic component using the present stiffeners described herein. It will also be understood that any property described herein for a specific method may hold for any of the methods described herein. Furthermore, it will be understood that for any semiconductor package and the methods described herein, not necessarily all the components or operations described will be shown in the accompanying drawings or method, but only some (not all) components or operations may be disclosed.

To more readily understand and put into practical effect the semiconductor package having present stiffeners interposers, they will now be described by way of examples. For the sake of brevity, duplicate descriptions of features and properties may be omitted.

### EXAMPLES

Example 1 provides a device including a first lateral member and a vertical member, for which the first lateral member and the vertical member form a frame structure that encloses the perimeter of a package substrate of a semiconductor package, and the vertical member having an upper end connected to the first lateral member and a lower end extending downward from the first lateral member for connecting to a printed circuit board.

Example 2 may include the device of example 1 and/or any other example disclosed herein, for which the frame structure formed by the first lateral member and the vertical member has an L-shaped cross-section; in particular, an inverted L-shape.

Example 3 may include the device of example 1 and/or any other example disclosed herein, further including a second lateral member, for which the second lateral member extends horizontally from the lower end of the vertical member.

Example 4 may include the device of example 3 and/or any other example disclosed herein, for which the second lateral member extends horizontally inward within a vertical footprint of the first lateral member.

Example 5 may include the device of example 4 and/or any other example disclosed herein, for which the frame structure formed by the first lateral member, the vertical member, and the second lateral member has a U-shaped cross-section; in particular, a sideways U-shape.

Example 6 may include the device of example 3 and/or any other example disclosed herein, for which the second lateral member extends horizontally outward to extend a vertical footprint of the frame structure.

Example 7 may include the device of example 6 and/or any other example disclosed herein, for which the frame structure formed by the first lateral member, the vertical member, and the second lateral member has a zig-zag-shaped cross-section.

Example 8 may include the device of example 3 and/or any other example disclosed herein, for which each of the first lateral member, the vertical member, and the second lateral member have metallization layers and vias to provide electrical pathways between the semiconductor package and the printed circuit board.

Example 9 may include the device of example 1 and/or any other example disclosed herein, for which the frame structure includes a ceramic material.

Example 10 may include the device of example 1 and/or any other example disclosed herein, for which the frame structure includes an assembled structure made from several subcomponents.

Example 11 provides a method including forming a stiffener, for which the stiffener includes a first lateral member and a vertical member, providing a package substrate for a semiconductor package, for which the package substrate includes a top surface, side surfaces, and a bottom surface, disposing at least one semiconductor die onto the top surface of the package substrate to form the semiconductor package, and disposing the stiffener on the package substrate, for which the first lateral member is disposed on the top surface and the vertical member is disposed proximally to the side surfaces of the package substrate.

Example 12 may include the method of example 11 and/or any other example disclosed herein, further including disposing a solder ball grid array on the semiconductor package.

Example 13 may include the method of example 12 and/or any other example disclosed herein, further including disposing the semiconductor package on a printed circuit board and coupling the semiconductor package and the stiffener to the printed circuit board.

Example 14 may include the method of example 11 and/or any other example disclosed herein, for which forming the stiffener includes providing ceramic sheets, stacking the ceramic sheets, dicing the ceramic sheets to form the stiffener into a desired shape, and sintering the stiffener.

Example 15 may include the method of example 14 and/or any other example disclosed herein, for which forming the stiffener further includes forming the vias and metallization using a screen printing process and stacking the ceramic sheets having the vias and metallization layers to form laminated structures before dicing the ceramic sheets to form the stiffener in a desired shape.

Example 16 provides an electronic component including a semiconductor package including a package substrate having a periphery, a plurality of solder balls attached to the package substrate, a frame structure enclosing the periphery of the package substrate and the plurality of solder balls, and a printed circuit board, with the frame structure and the plurality of solder balls being attached to the printed circuit board.

Example 17 may include the electronic component of example 16 and/or any other example disclosed herein, for which the package substrate includes a thin core substrate or coreless substrate.

Example 18 may include the electronic component of example 16 and/or any other example disclosed herein, for which the frame structure includes vias and metallization layers that provide an electrical bridge between the semiconductor package and the printed circuit board.

Example 19 may include the electronic component of example 16 and/or any other example disclosed herein, for which the frame structure includes a ceramic material.

Example 20 may include the electronic component of example 16 and/or any other example disclosed herein, for which the frame structure includes an assembled structure made from several subcomponents.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

The terms “and” and “or” herein may be understood to mean “and/or” as including either or both of two stated possibilities.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. A device comprising:
a first lateral member and a vertical member, wherein the first lateral member and the vertical member form a frame structure that encloses a package substrate of a semiconductor package; and
the vertical member having an upper end connected to the first lateral member and a lower end extending downward from the first lateral member for connecting to a printed circuit board.

2. The device of claim 1, wherein the frame structure is formed by the first lateral member and the vertical member has an L-shaped cross-section.

3. The device of claim 1, further comprising a second lateral member, wherein the second lateral member extends horizontally from the lower end of the vertical member.

4. The device of claim 3, wherein the second lateral member extends horizontally inward within a vertical footprint of the first lateral member.

5. The device of claim 4, wherein the frame structure formed by the first lateral member, the vertical member, and the second lateral member has a U-shaped cross-section.

6. The device of claim 3, wherein the second lateral member extends horizontally outward to extend a vertical footprint of the frame structure.

7. The device of claim 6, wherein the frame structure formed by the first lateral member, the vertical member, and the second lateral member has a zig-zag-shaped cross-section.

8. The device of claim 3, wherein each of the first lateral member, the vertical member, and the second lateral member have metallization layers and vias to provide electrical pathways between the semiconductor package and the printed circuit board.

9. The device of claim 1, wherein the frame structure comprises a ceramic material.

10. The device of claim 1, wherein the frame structure comprises an assembled structure made from several subcomponents.

11. A method comprising:
forming a stiffener, wherein the stiffener comprises a first lateral member and a vertical member;
providing a package substrate for a semiconductor package, wherein the package substrate comprises a top surface, side surfaces, and a bottom surface;
disposing at least one semiconductor die onto the top surface of the package substrate to form the semiconductor package; and
disposing the stiffener on the package substrate, wherein the first lateral member is disposed on the top surface and the vertical member is disposed proximally to the side surfaces of the package substrate.

12. The method of claim 11, further comprising disposing a solder ball grid array on the semiconductor package.

13. The method of claim 12, further comprising disposing the semiconductor package on a printed circuit board and coupling the semiconductor package and the stiffener to the printed circuit board.

14. The method of claim 11, wherein forming the stiffener comprises:
providing ceramic sheets;
stacking and laminating the ceramic sheets;
dicing the ceramic sheets to form the stiffener into a desired shape; and
sintering the stiffener.

15. The method of claim 14, wherein forming the stiffener further comprises:
forming the vias and metallization layers in the ceramic sheets using a screen printing process; and
stacking the ceramic sheets having the vias and metallization layers to form laminated structures before dicing the ceramic sheets to form the stiffener in a desired shape.

16. An electronic component comprising:
a semiconductor package comprising a package substrate having a periphery;
a plurality of solder balls attached to the package substrate;
a frame structure enclosing the periphery of the package substrate and the plurality of solder balls; and
a printed circuit board, wherein the frame structure and the plurality of solder balls are attached to the printed circuit board.

17. The electronic component of claim 16, wherein the package substrate comprises a thin core substrate or coreless substrate.

18. The electronic component of claim 16, wherein the frame structure comprises vias and metallization layers that provide an electrical bridge between the semiconductor package and the printed circuit board.

19. The electronic component of claim 16, wherein the frame structure comprises a ceramic material.

20. The electronic component of claim 16, wherein the frame structure comprises an assembled structure made from several subcomponents.
